(19) United States
(12) Patent Application Publication
(10) Pub. No.: US 2021/0029457 A1
(43) Pub. Date: Jan. 28, 2021

(54) Speaker Box and Mobile Terminal

(71) Applicant: AAC Technologies Pte. Ltd., Singapore city (SG)

(72) Inventors: Xingzhi Huang, Shenzhen (CN); Lin Liu, Shenzhen (CN); Dijiang Tong, Shenzhen (CN); Zhe Zhang, Shenzhen (CN); Jun Wu, Shenzhen (CN); Zhichen Chen, Shenzhen (CN); Zhaoyu Yin, Shenzhen (CN)

(21) Appl. No.: 16/994,642

(22) Filed: Aug. 16, 2020

Related U.S. Application Data
(63) Continuation of application No. PCT/CN2019/097418, filed on Jul. 24, 2019.

(30) Foreign Application Priority Data
Jul. 22, 2019 (CN) 201921159153.5

(51) Int. Cl. H04R 9/02; H04R 1/02; H04R 1/28; H05K 7/20

(52) U.S. Cl. CPC H04R 9/022; H04R 1/025; H04R 2201/02; H05K 7/20263; H04R 1/2811

(57) ABSTRACT

The present application discloses a speaker box including a housing body with an accommodation space and a speaker unit accommodated in the accommodation space. The speaker unit includes a diaphragm separating the accommodation space into a front acoustic cavity and a back cavity. The speaker box further has a heat conductor disposed on the housing body. The heat conductor is used to conduct the heat generated by the heating element to the sound channel and the front acoustic cavity. The mobile terminal adopts the speaker box. Comparing with the related technology, the speaker box provided by the present application can sound and dissipate heat for the mobile terminal.

### FIELD OF THE PRESENT DISCLOSURE

The present application relates to technical field of electroacoustic transducers, especially to a speaker box with heat dissipation function.

### DESCRIPTION OF RELATED ART

With the advent of the mobile Internet Era, smart mobile devices are increasing. Among many mobile terminals, mobile phone is undoubtedly the most common and portable mobile terminal. At present, the functions of mobile phones are extremely diverse, one of which is the function of high-quality music, so the speaker box used to play sound has been widely applied to the current intelligent mobile terminals.

The speaker box of the related technology comprises a housing body with an accommodation space, a speaker unit accommodated in the housing body and a sound channel formed in the accommodation space. The speaker unit comprises a diaphragm used for vibrating and sounding. The diaphragm separates the accommodation space into a front acoustic cavity and a back cavity. The sound channel connects the front acoustic cavity with outside and forms a front cavity with the front acoustic cavity to sound.

However, all parts of the mobile terminal of the mobile phone of related technology will generate plenty of heat and the heat will influence the work performance of all parts inside the mobile terminal. The speaker box of the related technology generally is only used for sounding and can not dissipate the heat inside the mobile terminal limiting the purpose of the speaker box.

### SUMMARY OF THE INVENTION

One of the major objects of the invention is to provide a speaker box with improved heat dissipation efficiency.

Accordingly, the present invention provides a speaker box, comprising:

a housing body with an accommodation space;

a speaker unit accommodated in the accommodation space, and comprising a diaphragm separating the accommodation space into a front acoustic cavity and a back cavity arranged opposite to the front acoustic cavity;

wherein

the speaker box further comprises a heat conductor conducting the heat generated by a heating element into the speaker box;

the heat conductor is disposed on the housing body and extends by fitting the external surface of the housing body, bends and forms a sound channel communicating the front acoustic cavity with outside of the housing body;

the heat conductor is used to conduct the heat generated by the heating element into the sound channel and the front acoustic cavity.

Further, the housing body comprises an upper cover and a lower cover forming the accommodation space by cooperating with the upper cover; the upper cover comprises a top wall arranged in intervals and opposite to the diaphragm, a support wall extending from the top wall to support the speaker unit, a side wall extending and bending from the periphery of the top wall to the direction near the lower cover and an extension wall extending from the side wall to the support wall; the heat conductor fits to the external surface of the lower cover, bends and extends to the extension wall and encircles the sound channel with the extension wall together.

Further, the heat conductor comprises a heat conduction part connected with the heating element, a heat dissipation part connected with the extension wall and a heat transfer part connected with the heat conduction part and the heat dissipation part; the heat transfer part comprises a body part connected with the heat conduction part and a bending part bending and extending from the body part and connecting with the heat dissipation part; the body part fits the surface of the lower cover and extends; the surface of the bending part flushes with the external surface of the side wall.

Further, a sunken groove sunken and formed away from the surface of one side of the accommodation space near the direction of the accommodation space is set on the side wall; the bending part is accommodated in the sunken groove; an accommodation slot sunken and formed from the surface near one side of the sound channel to the direction away from the sound conduction is set on the extension wall; the heat dissipation part is accommodated in the accommodation slot; and the accommodation slot connects with the sunken groove mutually.

Further, the extension wall comprises two parallel walls arranged oppositely and in intervals and two inclined walls connecting the two parallel walls; the parallel wall is set along the vibration direction of the diaphragm; the inclined wall comprises a first inclined wall near the direction of the lower cover and a second inclined wall arranged oppositely and in intervals with the first inclined wall; the accommodation slot is set on the first inclined wall.

Further, the heat dissipation part forms the surface of the sound channel, which is at the same level with that of the sound channel formed by the first inclined wall.

Further, the body part comprises a first part connected with the heat conduction part and a second part connected with one side of the first part away from the heat conduction part; the bending part is formed by bending and extending from one side of the second part away from the first part; the width of the first part and the heat conduction part are equal; the width of the second part, the bending part and the heat dissipation part are equal and the width of the second part is larger than that of the first part.

Further, the cross-sectional area of the sound channel reduces gradually from the direction away from the front acoustic cavity to that near the front acoustic cavity; the heat dissipation part is set inclinely to the bending part.

Further, the heat conductor is solid structure.

Further, the heat conductor has a hollow area, and condensate liquid is filled in the hollow area.

The present invention further provides a mobile terminal, comprising a housing with a containment space, a heating element accommodated in the containment space, and a speaker box as described above, wherein the heat conductor of the speaker box is connected with the heating element.

Further, the heating element is a CPU or a battery.

### BRIEF DESCRIPTION OF THE DRAWINGS

Many aspects of the exemplary embodiment can be better understood with reference to the following drawings. The components in the drawing are not necessarily drawn to scale, the emphasis instead being placed upon clearly illustrating the principles of the present disclosure.

FIG. 1 is an isometric view of a speaker box provided by an embodiment of the invention;

FIG. 2 is an exploded view of the speaker box shown in FIG. 1.

FIG. 3 is a cross-sectional view taken along line III-III in FIG. 1.

FIG. 4 is an isometric view of a mobile terminal provided by the embodiment present application.

### DETAILED DESCRIPTION OF THE EXEMPLARY EMBODIMENT

The present disclosure will hereinafter be described in detail with reference to an exemplary embodiment. To make the technical problems to be solved, technical solutions and beneficial effects of the present disclosure more apparent, the present disclosure is described in further detail together with the figure and the embodiment. It should be understood the specific embodiment described hereby is only to explain the disclosure, not intended to limit the disclosure.

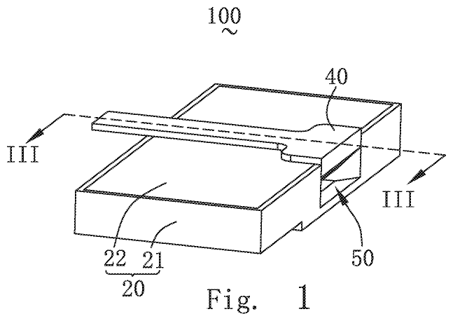

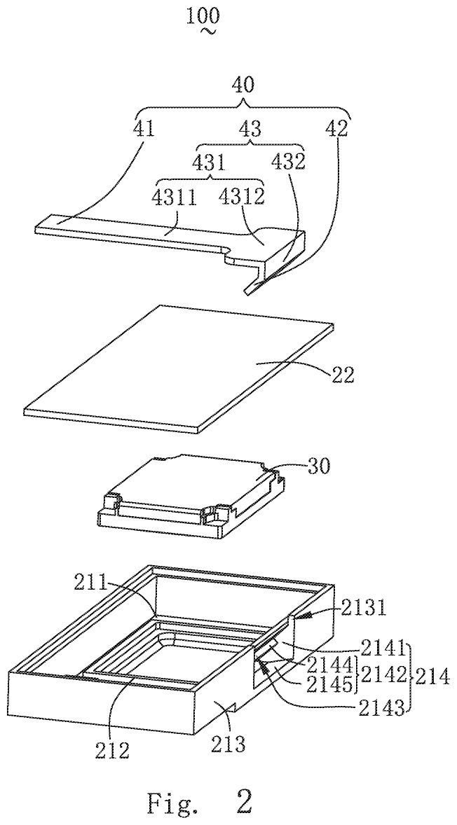

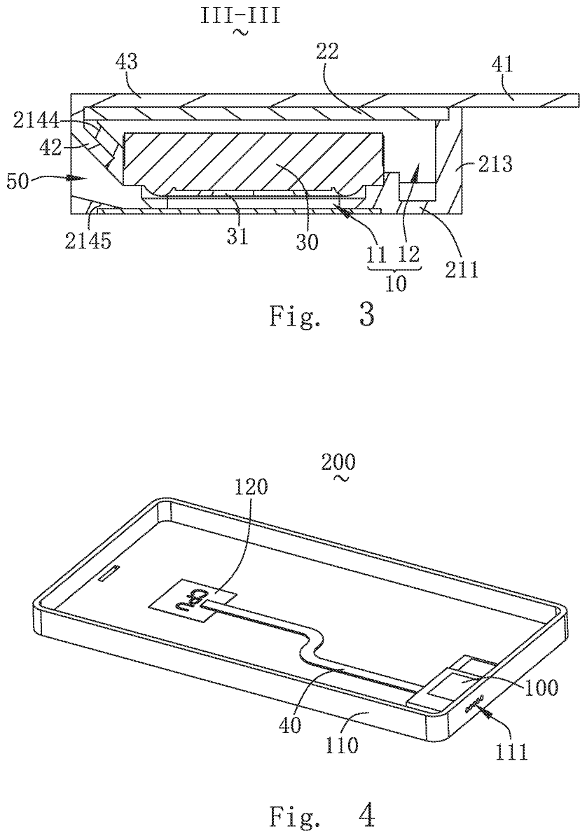

Please refer to FIGS. 1-3. The present application provides a speaker box 100, comprising a housing body 20 with an accommodation space 10, a speaker unit 30 accommodated in the accommodation space 10 and a heat conductor 40 used for conducting the heat generated by a heating element into the speaker box 100. The speaker unit 30 comprises a diaphragm 31 used for vibrating and sounding. The diaphragm 31 separates the accommodation space 10 into a front acoustic cavity 11 and a back cavity 12 arranged opposite to the front acoustic cavity 11. The heat conductor 40 is lapped on the housing body 20. The heat conductor 40 extends by fitting the external surface of the housing body 20, bends and forms a sound channel 50 connecting the front acoustic cavity 11 with outside together with the housing body 20. The heat conductor 40 is used to conduct the heat generated by the heating element to the sound channel 50 then to the front acoustic cavity 11.

The housing body 20 comprises an upper cover 21 and a lower cover 22 forming the accommodation space 10 by cooperating with the upper cover 21. The upper cover 21 comprises a top wall 211 set in intervals and oppositely with the diaphragm 31, a support wall 212 extending from the top wall 211 to support the speaker unit 30, a side wall 213 bending and extending from the outer edge of the top wall 211 to the direction near the lower cover 22 and an extension wall 214 extending from the side wall 213 to the support wall 212. The heat conductor 40 fits on the external surface of the lower cover 21, bends and extends to the extension wall 214 and encircles the sound channel 50 with the extension wall 214.

Four pieces are set on the side wall 213. The lower cover 22 is covered on the side wall 213. The extension wall 214 is formed by extending from the side wall 213 to the support wall 212. A sunken groove 2131 depressed and formed from the surface of one side away from the accommodation space 10 to the direction near the accommodation space 10 is set on the side wall 213. The side wall 213 connected with the extension wall 214 is set on the sunken groove 2131.

The extension wall 214 comprises two parallel walls 2141 arranged oppositely and in intervals, and two inclined walls 2142 connecting the two parallel walls 2141. The parallel wall 2141 is set along the vibration direction of the diaphragm 31 and the two parallel walls 2141 are parallel to each other. The inclined wall 2142 comprises a first inclined wall 2144 near the lower cover 22 and a second inclined wall 2145 set in intervals and opposite to the first inclined wall 2144.

The extension wall 214 also comprises an accommodation slot 2143 depressed and formed from the surface near one side of the sound channel 50 to the direction away from the sound channel 50. The accommodation slot 2143 interconnects with the sunken groove 2131. The accommodation slot 2143 is set on the first inclined wall 2144. The cross-section area of the sound channel 50 reduces gradually from the direction away from the front acoustic cavity 11 to the direction near the front acoustic cavity 11. Specifically, along the direction away from the front acoustic cavity 11 to the direction near the front acoustic cavity 11, the first inclined wall 2144 and the second inclined wall 2145 tilts and extends from the direction near the lower cover 22 to the direction near the top wall 211 and the tilt angle of the first inclined wall 2144 and that of the second inclined wall 2145 are different. The included angle between the first inclined wall 2144 and the side wall 213 is less than that between the second inclined wall 2145 and the side wall 213.

The heat conductor 40 comprises a heat conduction part 41 connected with the heating element, a heat dissipation part 42 connected with the extension wall 214, a heat transfer part 43 connecting the heat conduction part 41 and the heat dissipation part 42. The heat conduction part 41, the heat dissipation part 42 and the heat transfer part 43 are integrally formed to increase the stability of connection among the heat conduction part 41, the heat dissipation part 42 and the heat transfer part 43.

The heat transfer part 43 comprises a body part 431 connecting with the heat conduction part 41 and a bending part 432 bending and extending from the body part 431 and connecting the heat dissipation part 42. The body part 431 extends by fitting the surface of the lower cover 22. The bending part 432 and the body part 431 are set mutually vertically. The heat dissipation part 42 is set inclinedly to the bending part 432. The bending part 432 is accommodated in the sunken groove 2131. The heat dissipation part 42 is accommodated in the accommodation slot 2143.

The surface of the sound channel 50 formed by the heat dissipation part 42 is at the same level with that of the sound channel 50 formed by the first inclined wall 2144, namely the heat dissipation part 42 is accommodated in the accommodation slot 2143 completely. The depression depth of the accommodation slot 2143 is the same as the thickness of the heat dissipation part 42 to make the heat dissipation part 42 flush with the first inclined wall 2144 and no such a sound channel 50 can be blocked to ensure the volume of the sound channel 50. The sounding of the sound channel 50 is not influenced on the basis that the dissipation of heat can be realized.

The surface of the bending part 432 is flush with the external surface of the side wall 213. The surface of the side wall 213 with the sunken groove 2131 away from one side of the accommodation space 10 is at the same level with that of one side of the bending part 432 away from the accommodation space 10 are at the same flat surface, namely, the bending part 432 is accommodated in the sunken groove 2131 completely. The depression depth of the sunken groove 2131 is the same as that of thickness of the bending part 432 to make the bending part 432 flush with the side wall 213 and will not extend out of the side wall 213 to make the outside of the speaker box 100 more smooth and the speaker box 100 assembled better.

The body part 431 comprises a first part 4311 connected with the heat conduction part 41 and a second part 4312 connected with one side of the first part 4311 away from the heat conduction part 41, the bending part 432 formed by bending and extending from one side of the second part 4312 away from the first part 4311. The width of the first part 4311 is the same as that of the heat conduction part 41. The width of the second part 4312, the bending part 432 and the heat dissipation part 432 are the same and the width of the second part 4312 is larger than that of the first part 4311 to make the heat conductor 40 connect and fix the housing body 20 and increase the area of the heat dissipation part 42 to improve the heat dissipation performance of the heat conductor 40.

In embodiment, the heat conductor 40 is solid structure. Of course, in other embodiments, the heat conductor 40 can be hollow structure. The heat conductor 40 has a hollow area and the hollow area is filled with condensate liquid adding the effect of dissipation of heat of the heat conductor 40. Even, the heat conductor 40 can be any structures conducting heat, namely only the heat conductor 40 can be set and conduct the heat of the heating element to the speaker box 100 and realize the dissipation of heat through the speaker box 100.

The working principle of heat dissipation of the speaker box 100: when the speaker box 100 dissipates heat, the pulse signal of lower frequency (lower than 1000 Hz) can be input to drive the diaphragm 31 to vibrate. Under the pulse signal, the diaphragm 31 can only vibrates and cannot sound. The vibration of the diaphragm 31 pushes the air convection of the front acoustic cavity 11 and the sound channel 50 with the air out of the speaker box 100 to realize air cooling and heat dissipation. When the speaker box 100 does not execute the task of playing sound, pulse signal of lower frequency can be input individually to let the speaker box 100 used for dissipating heat. When the speaker box 100 executes the task of playing sound, the pulse signal of lower frequency can be superposed into music signal. As the pulse signal is ultra-low frequency, it will not be heard by human ears and the play effect of the speaker box 100 will not be influenced.

Specifically, when the diaphragm 31 vibrates near the direction of the top wall 211 and the heat conductor 40 gives the relatively hot air in the front acoustic cavity 11 out of the speaker box 100. When the diaphragm 31 vibrates towards the direction away from the top wall 211 and inhales the relatively cool air outside the speaker box 100 into the front acoustic cavity 11 through the sound channel 50 to realize the heat dissipation effect by reciprocating.

Please refer to FIG. 4, at the same time, the present application also provides one kind of a mobile terminal 200, comprising a housing 110 with a containment space, a heating element 120 accommodated in the housing 110 and the speaker box 100. The heat conductor 40 of the speaker box 100 is connected with the heating element 120. The heat generated by the heating element 120 is transmitted to the speaker box 100 through the heat conductor 40. The speaker box 100 cools air and dissipates heat through the vibration of the diaphragm 31.

A sound outlet 111 is set on the housing 110. The sound outlet 111 is connected with the sound channel 50. The speaker box 100 sounds through the sound outlet 111 and gives out the hot air from the mobile terminal 200 through the sound outlet 111.

In this emission, the heating element 120 is a central processor. Of course, in other embodiments, the heating element 120 can be any part of the battery or the mobile terminal 200 that needs dissipate heat.

It should be noted that the heat conductor 40 in the embodiment only connects central processor. Of course, in other embodiments, the heat conductor 40 can connect several parts that need dissipate heat at the same time, such as central processor, battery or any parts needing dissipation of heat and dissipate heat for several parts that need dissipate heat through the speaker box 100.

It can be understood that the shape and length of the heat conduction part 41 of the heat conductor 40 of the speaker box 100 can be chosen according to the actual demand, only if the heat conduction part 41 can conduct the heat generated by the heating element 120 to the speaker box 100.

Compared with the related art, in the speaker box provided by the present application, through the arrangement of a heat conductor, the heat conductor introduces heat generated by a heating element into the speaker box, discharging of the heat is achieved through the speaker box, and the speaker box can be used not only for making a sound, but also for dissipating the heat, so that applications of the speaker box are increased and the speaker box has a better application prospect.

Correspondingly, in the mobile terminal provided by the present application, by adopting the speaker box, the speaker box can be used for making the sound while dissipating the heat, so that, when the heating element in the speaker box emits heat to work, the speaker box can discharge the heat emitted from the heating element out of the mobile terminal. The speaker box can ensure the working performance of the heating element while saving the internal space of the mobile terminal.

It is to be understood, however, that even though numerous characteristics and advantages of the present exemplary embodiment have been set forth in the foregoing description, together with details of the structures and functions of the embodiment, the disclosure is illustrative only, and changes may be made in detail, especially in matters of shape, size, and arrangement of parts within the principles of the invention to the full extent indicated by the broad general meaning of the terms where the appended claims are expressed.

What is claimed is:

1. A speaker box, comprising:
a housing body with an accommodation space;
a speaker unit accommodated in the accommodation space, and
comprising a diaphragm separating the accommodation space into a front acoustic cavity and a back cavity arranged opposite to the front acoustic cavity;
wherein
the speaker box further comprises a heat conductor conducting the heat generated by a heating element into the speaker box;
the heat conductor is disposed on the housing body and extends by fitting the external surface of the housing body, bends and forms a sound channel communicating the front acoustic cavity with outside of the housing body;
the heat conductor is used to conduct the heat generated by the heating element into the sound channel and the front acoustic cavity.

2. The speaker box as described in claim 1, wherein, the housing body comprises an upper cover and a lower cover forming the accommodation space by cooperating with the upper cover; the upper cover comprises a top wall arranged in intervals and opposite to the diaphragm, a support wall extending from the top wall to support the speaker unit, a side wall extending and bending from the periphery of the top wall to the direction near the lower cover and an extension wall extending from the side wall to the support wall; the heat conductor fits to the external surface of the lower cover, bends and extends to the extension wall and encircles the sound channel with the extension wall together.

3. The speaker box as described in claim 2, wherein, the heat conductor comprises a heat conduction part connected with the heating element, a heat dissipation part connected with the extension wall and a heat transfer part connected with the heat conduction part and the heat dissipation part; the heat transfer part comprises a body part connected with the heat conduction part and a bending part bending and extending from the body part and connecting with the heat dissipation part; the body part fits the surface of the lower cover and extends; the surface of the bending part flushes with the external surface of the side wall.

4. The speaker box as described in claim 3, wherein, a sunken groove sunken and formed away from the surface of one side of the accommodation space near the direction of the accommodation space is set on the side wall; the bending part is accommodated in the sunken groove; an accommodation slot sunken and formed from the surface near one side of the sound channel to the direction away from the sound conduction is set on the extension wall; the heat dissipation part is accommodated in the accommodation slot; and the accommodation slot connects with the sunken groove mutually.

5. The speaker box as described in claim 4, wherein, the extension wall comprises two parallel walls arranged oppositely and in intervals and two inclined walls connecting the two parallel walls; the parallel wall is set along the vibration direction of the diaphragm; the inclined wall comprises a first inclined wall near the direction of the lower cover and a second inclined wall arranged oppositely and in intervals with the first inclined wall; the accommodation slot is set on the first inclined wall.

6. The speaker box as described in claim 5, wherein, the heat dissipation part forms the surface of the sound channel, which is at the same level with that of the sound channel formed by the first inclined wall.

7. The speaker box as described in claim 4, wherein, the body part comprises a first part connected with the heat conduction part and a second part connected with one side of the first part away from the heat conduction part; the bending part is formed by bending and extending from one side of the second part away from the first part; the width of the first part and the heat conduction part are equal; the width of the second part, the bending part and the heat dissipation part are equal and the width of the second part is larger than that of the first part.

8. The speaker box as described in claim 4, wherein, the cross-sectional area of the sound channel reduces gradually from the direction away from the front acoustic cavity to that near the front acoustic cavity; the heat dissipation part is set inclinely to the bending part.

9. The speaker box as described in claim 1, wherein, the heat conductor is solid structure.

10. The speaker box as described in claim 1, wherein, the heat conductor has a hollow area, and condensate liquid is filled in the hollow area.

11. A mobile terminal, comprising a housing with a containment space, a heating element accommodated in the containment space, and a speaker box as described in claim 1, wherein the heat conductor of the speaker box is connected with the heating element.

12. The mobile terminal as described in claim 11, wherein, the heating element is a CPU or a battery.
